(19) United States
(12) Patent Application Publication
(10) Pub. No.: US 2005/0023637 A1
(43) Pub. Date: Feb. 3, 2005

(54) Method for producing an antifuse structure and antifuse

(76) Inventors: Jurgen Lindolf, Friedberg (DE); Florian Schamberger, Munchen (DE)

Correspondence Address: GERO G. McCLELLAN;MOSER, PATTERSON & SHERIDAN, L.L.P., Suite 1500, 3040 Post Oak Blvd., Houston, TX, 77056, US

(21) Appl. No.: 10/724,009

(22) Filed: Nov. 26, 2003

(30) Foreign Application Priority Data
Nov. 28, 2002 (DE) 102 55 425.0

(51) Int. Cl. H01L 29/00

(52) U.S. Cl. 257/530

(57) ABSTRACT

The invention relates to a method for producing an antifuse structure in a substrate, a conductive region and a nonconductive region adjoining the latter being formed in the substrate, so that an edge of the conductive region is produced, a dielectric layer being deposited in such a way that it covers at least a part of the edge.

### CROSS-REFERENCE TO RELATED APPLICATIONS

This application claims foreign priority benefits under 35 U.S.C. §119 to co-pending German patent application 102 55 425.0, filed Nov. 28, 2002. This related patent application is herein incorporated by reference in its entirety.

### BACKGROUND OF THE INVENTION

1. Field of the Invention

The invention relates to a method for producing an antifuse structure in a substrate and an antifuse for integration into a substrate.

2. Description of the Related Art

Antifuse structures are used in integrated circuits to define permanent setting values such as, e.g., for the adjustment of active and passive electronic components, for the replacement of defective memory areas by redundant memory areas, etc. The setting values are defined by so-called “blowing” of the antifuse structures, for which purpose a programming voltage is applied to the antifuse structure, which leads to a breakdown in a dielectric, the breakdown channel in the dielectric permanently acquiring low impedance.

Antifuse structures have been produced hitherto in which essentially electrodes and dielectric are formed as three layers that are essentially parallel to one another and arranged vertically one above the other. Since the thickness of the dielectric is usually the same in the active region of the antifuse structure, a breakdown takes place purely stochastically at the weakest point of the dielectric.

The programming voltage with which an antifuse structure can be changed over to a low-impedance state is relatively high compared with the operating voltage provided for the integrated circuit. Therefore, it is necessary to take particular precautions in order, during the programming of the antifuses, to avoid the situation in which, in the event of poor insulation of the interconnects carrying the programming voltage with respect to adjacent structures, the integrated circuit undergoes a breakdown at locations which are not provided therefor. Therefore, it is necessary to keep the programming voltage for an antifuse structure as low as possible in order to avoid a later malfunction in the integrated circuit on account of breakdowns at undesirable locations.

It is an object of the present invention to provide an antifuse structure and a method for producing an antifuse structure, it being possible to reduce the programming voltage of the antifuse structure, with the result that the antifuse structure can be programmed with lower programming voltages.

This object is achieved by means of the method for producing an antifuse structure according to claim 1 and the antifuse according to claim 6.

Further advantageous refinements of the invention are specified in the dependent claims.

### SUMMARY OF THE INVENTION

A first aspect of the present invention provides a method for producing an antifuse structure in a substrate, preferably in a semiconductor substrate. A conductive region and a nonconductive region adjoining the latter are formed in the substrate, which regions form a common surface, preferably a common surface with the substrate surface, so that an edge of the conductive region is produced. A dielectric layer is deposited in such a way that it covers the edge at least in part.

In this way, it is possible to produce an antifuse structure in which the position of the desired breakdown channel is defined in the region of the edge. By virtue of the fact that, upon application of the programming voltage, the largest field strength arises in the region of the edge, it is probable that the breakdown through the dielectric layer takes place near the edge. By means of increasing the field strength in the region of the edge with the programming voltage having been applied, it is furthermore possible to use a lower programming voltage for programming the antifuse structure since the breakdown is dependent on the field strength.

The conductive region may be designed in such a way that it has a corner in a lateral extent, the dielectric layer being applied such that it extends over the corner. In this way, it is possible to achieve a further increase in the field strength with the programming voltage having been applied. Furthermore, the region of the later breakdown channel is defined in the region of the corner.

Preferably, the conductive region is designed as a highly doped semiconductor region. The nonconductive region may comprise SiO₂, SiN or other materials which are nonconductive and have a dielectric with the highest possible dielectric constant.

A further aspect of the present invention provides an antifuse having a first conductive region, a dielectric layer and a second conductive region. The first conductive region is formed in a manner adjoining a nonconductive region, with the result that an edge running parallel to the surface of the substrate is formed. The first conductive region and the nonconductive region preferably form a common surface above which the dielectric layer is applied, which is arranged at least partly above the edge.

Such an antifuse has the advantage that the field strength is increased in the region of the edge given a constant programming voltage in comparison with conventional antifuses, with the result that lower programming voltages suffice for bringing about a breakdown and thus causing the antifuse to acquire low impedance. This reduces the risk of the increased programming voltage bringing about breakdowns at other locations within the integrated circuit, which could lead to the integrated circuit being damaged or destroyed.

It may be provided that the form of the first conductive region has a corner in a surface direction, the dielectric layer being arranged above the corner. In the region of the corner, the field strength is increased in such a way that a breakdown can be achieved at a lower programming voltage.

### BRIEF DESCRIPTION OF THE DRAWINGS

Preferred embodiments of the invention are explained in more detail below with reference to the accompanying drawings.

In the figures:

FIG. 1 shows a cross section through a substrate with an antifuse structure in accordance with a first embodiment of the invention;

FIG. 2 shows a cross section through the substrate with an antifuse structure according to FIG. 1 with field lines depicted;

FIG. 3 shows a plan view of an antifuse structure in accordance with the embodiment according to FIG. 1; and

FIG. 4 shows a plan view of an antifuse structure in accordance with a second embodiment of the invention.

### DETAILED DESCRIPTION OF THE PREFERRED EMBODIMENT

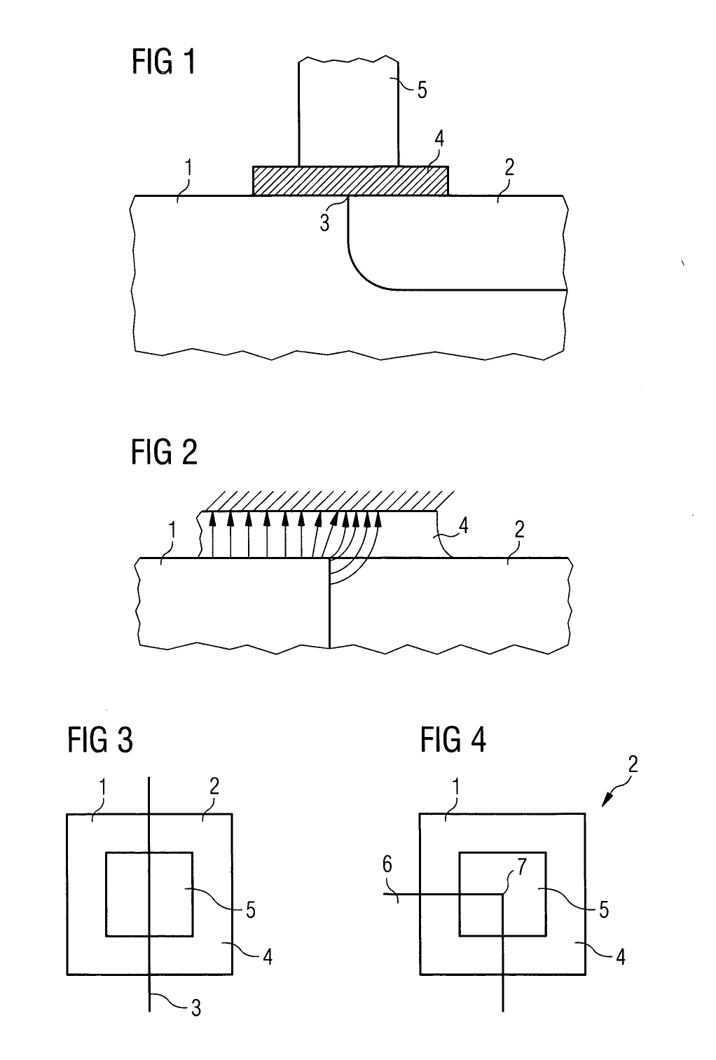

FIG. 1 illustrates a cross section through an antifuse structure in accordance with a first embodiment of the invention. The antifuse structure has a first conductive region 1 embedded in a semiconductor substrate. The first conductive region 1 may comprise a metal material or a doped, preferably highly doped, semiconductor material.

A nonconductive region 2 comprising silicon dioxide SiO₂ is arranged in a manner adjoining the first conductive region 1. The nonconductive region 2 is likewise embedded in the substrate, with the result that the first conductive region 1 and the nonconductive region 2 preferably have a common substrate surface. An edge 3 is thus formed at the boundary between the first conductive region 1 and the nonconductive region 2. A dielectric layer 4, which preferably comprises the material silicon nitrite SiN, is applied over the edge. A second conductive region 5 is applied over the dielectric layer 4.

An antifuse structure comprising the first conductive region 1, the dielectric layer 4 and the second conductive region 5 is formed in this way.

In order to program such a structure, by applying a programming voltage between the first and second conductive regions 1, 5, a breakdown channel is produced in the dielectric 4 which permanently remains at low impedance. The breakdown channel preferably forms at the location in the dielectric at which the largest field strength occurs.

FIG. 2 illustrates that the largest field strength occurs in the dielectric in the region of the edge 3. The field lines which proceed from that part of the edge which extends into the depth increase the field strength of the field in the region of the edge.

The antifuse structure in accordance with FIG. 1 is produced with the aid of lithographic methods. For this purpose, in a substrate wafer, preferably in a semiconductor substrate, the first conductive region 1 is produced e.g. by introducing a doping. A nonconductive region 2 is produced in a manner adjoining the first conductive region 1 by oxidizing the semiconductor material in this region. The oxide grows both into the depth of the semiconductor substrate and up above, so that firstly an uneven surface of the substrate wafer is produced. The surface of the substrate wafer is leveled by means of a CMP method (Chemical Mechanical Polishing), thereby producing a sharp boundary between the first conductive region and the adjoining nonconductive region.

It goes without saying that such a structure can also be produced by a first conductive layer firstly being applied to a substrate wafer, e.g. by means of an epitaxy method, and a silicon dioxide layer or a different nonconductive material subsequently being applied in the region of the nonconductive layer 2. It is subsequently expedient to level the surface of the substrate wafer in order to achieve a sharp edge.

A dielectric layer 4 is deposited over the edge 3 thus formed and is subsequently patterned in such a way that it lies above the edge and the margins of the dielectric layer 4 are at a sufficient distance from the edge.

FIG. 3 illustrates a plan view of the antifuse in accordance with the first embodiment of the invention. The first conductive region 1 is evident, which terminates through an edge toward the nonconductive region 2. The dielectric layer 4 is applied over the first conductive region and nonconductive region 2 in such a way that it lies above the edge 3. The second conductive region 5 is situated on the dielectric layer.

FIG. 4 illustrates a second embodiment of an antifuse according to the invention. A third conductive region 6, having a corner 7, is provided instead of the first conductive region 1. The nonconductive region 2 adjoins the third conductive region 6, thereby forming two edges which run toward one another and meet at the corner 7. The dielectric layer 4 is placed over the third conductive region 6 and the nonconductive region 2 in such a way that the corner and preferably a part of the adjoining edges are covered by the dielectric layer 4. The second conductive region 5 is arranged on the dielectric layer 4 in such a way that the second conductive region 5 is arranged above the corner. In this way, a high field strength can form in the region of the corner 7 with the programming voltage having been applied, with the result that the breakdown channel is preferably formed in the region of the corner. Moreover, the same procedure as for the production of the first antifuse is applicable for the production of the antifuse in accordance with the second embodiment of the invention.

It goes without saying that more complex forms of the first conductive layer 1 may also be provided in order to form a plurality of preferred breakdown locations, such as e.g. a crenellated form, a saw blade form or the like.

It may also be provided that the first conductive region is part of a further component of the integrated circuit, e.g. a source or drain region of a transistor.

1. A method for producing an antifuse structure in a substrate, comprising:
forming a conductive region on the substrate, the conductive region defining a first upper surface and a first lateral boundary surface which meet at an angle to form an edge;
forming a nonconductive region adjoining the conductive region on the substrate, the nonconductive region defining a second upper surface and a second lateral boundary surface; wherein the first and second lateral boundary surfaces are in facing relationship and form an interface; and
forming a dielectric layer over at least a portion of the first upper surface of the conductive region and at least a portion of the edge, whereby an area of relatively increased field strength is produced during application of a programming voltage to form a breakdown channel in the dielectric layer.

2. The method of claim 1, forming a conductor on the dielectric layer.

3. The method of claim 1, wherein the conductive region defines a corner and wherein forming the dielectric layer comprises forming the dielectric layer over the corner.

4. The method of claim 1, wherein the first lateral boundary surface is substantially orthogonal to a lower surface of the dielectric layer interfacing with the edge.

5. The method of claim 1, wherein the conductive region is a doped semiconductor region.

6. The method of claim 1, wherein the nonconductive region comprises at least one of SiO₂ and SiN.

7. The method of claim 1, wherein the dielectric layer comprises SiN.

8. The method of claim 1, wherein the nonconductive region comprises at least one of SiO₂ and SiN and wherein the dielectric layer comprises SiN.

9. The method of claim 1, wherein the dielectric layer is disposed over at least a portion of the nonconductive region.

10. A method of blowing an antifuse, comprising:
a) providing an antifuse, comprising:
a conductive region, the conductive region defining a first upper surface and a first lateral boundary surface which meet at an angle to form an edge;
a nonconductive region adjoining the conductive region, the nonconductive region defining a second upper surface and a second lateral boundary surface; wherein the first and second lateral boundary surfaces are in facing relationship and form an interface; and
a dielectric layer disposed over at least a portion of the first upper surface of the conductive region and at least a portion of the edge; and
b) applying a programming voltage to the antifuse to form a breakdown channel in the dielectric layer, whereby an area of relatively increased field strength is produced along the edge.

11. The method of claim 10, wherein the conductive region defines a corner and wherein the dielectric layer is disposed over the corner and wherein applying the programming voltage results in a further area of relatively increased field strength.

12. The method of claim 10, wherein the dielectric layer is disposed over at least a portion of the nonconductive region.

13. The method of claim 10, wherein the antifuse further comprises a conductor on the dielectric layer.

14. An antifuse, comprising:
a first conductive region, the first conductive region defining a first upper surface and a first lateral boundary surface which meet at an angle to form an edge;
a nonconductive region adjoining the first conductive region, the nonconductive region defining a second upper surface and a second lateral boundary surface; wherein the first and second lateral boundary surfaces are in facing relationship and form an interface;
a dielectric layer disposed over at least a portion of the first upper surface of the first conductive region and at least a portion of the edge, whereby an area of relatively increased field strength is produced during application of a programming voltage to form a breakdown channel in the dielectric layer; and
a second conductive region on the dielectric layer.

15. The antifuse of claim 14, wherein the first conductive region defines a corner and wherein the dielectric layer is disposed over the corner.

16. The antifuse of claim 14, wherein the first conductive region and the nonconductive region form a substantially planar upper surface which interfaces with a lower surface of the dielectric layer.

17. The antifuse of claim 14, wherein the dielectric layer is disposed over at least a portion of the nonconductive region.

18. The antifuse of claim 14, wherein the nonconductive region comprises at least one of SiO₂ and SiN.

19. The antifuse of claim 14, wherein the dielectric layer comprises SiN.

20. The antifuse of claim 14, wherein the nonconductive region comprises at least one of SiO₂ and SiN and wherein the dielectric layer comprises SiN.
